(19) United States
(12) Patent Application Publication
(10) Pub. No.: US 2019/0165811 A1
(43) Pub. Date: May 30, 2019

(54) LOW DENSITY PARITY CHECK CODE DECODER AND DECODING METHOD THEREOF

(71) Applicant: Institute For Information Industry, Taipei (TW)

(72) Inventors: Huan-Chun WANG, Taipei City (TW); Jih-Wei LEE, Taipei City (TW); Ming-Ju WU, Taipei City (TW)

(21) Appl. No.: 15/829,973

(22) Filed: Dec. 3, 2017

(30) Foreign Application Priority Data
Nov. 28, 2017 (TW) 106141372

(51) Int. Cl. H03M 13/11; H03M 13/00

(52) U.S. Cl. CPC H03M 13/1131; H03M 13/1125; H03M 13/616

(57) ABSTRACT

An LDPC decoder determines j number of variable nodes related to a first check node based on a parity check matrix. The LDPC decoder calculates j number of node LLR values corresponding to the j number of variable nodes, and determines j number of initial CN-VN LLR values of the j number of variable nodes. The LDPC decoder calculates j number of VN-CN LLR values according to the j number of node LLR values and the j number of initial CN-VN LLR values, and calculates j number of updated CN-VN LLR values of the j number of variable nodes. The LDPC decoder calculates j number of updated node LLR values according to the j number of updated CN-VN LLR values and j number of VN-CN LLR values, and updates the j number of node LLR values of the j number of variable nodes by the updated node LLR values.

### PRIORITY

This application claims priority to Taiwan Patent Application No. 106141372 filed on Nov. 28, 2017, which is hereby incorporated by reference in its entirety.

### FIELD

The present invention relates to a decoder and a decoding method thereof. More particularly, the present invention relates to a low-density parity check (LDPC) decoder and a decoding method thereof.

### BACKGROUND

A low-density parity check (LDPC) code, as a kind of error correction code, is mainly configured to determine and correct errors in data transmission. The encoding of the LPDC code is mainly performed using a general standard currently, but decoding methods thereof are rather diversified. Common LDPC decoding methods used currently include a Sum-Product Algorithm (SPA), a Log Sum-Product Algorithm (LSPA) and a Min-Sum Algorithm (MSA).

For the above three algorithms, the SPA has a higher encoding accuracy, but various likelihood ratio (LR) values are usually calculated by multiplication in the operation thereof, so the speed of the SPA is relatively slow. Accordingly, the LSPA mainly makes improvement on the excessive multiplication operations of the SPA to first process the LR values into Log Likelihood (LLR) values by logarithm operation. In this way, the multiplication operation in the SPA may be done by additive operation in the LSPA. Although the LSPA has a lower accuracy, the speed thereof can be improved remarkably.

On the other hand, in consideration of the fact that tanh and tanh⁻¹ operations are still required when calculating check node to variable node (CN-VN) LLR values in the LSPA, the MSA calculates relevant CN-VN LLR values mainly based on minimum variable node to check node (VN-CN) LLR values. In this way, the tanh and tanh⁻¹ operations can be avoided to further improve the operational speed.

However, the aforesaid three algorithms all first utilize all the variable nodes to estimate LR values that can be provided by each check node for different variable nodes, and then estimate reversely the LR value of each of the variable nodes according to the estimated LR values that can be provided by the check nodes for different variable nodes. Therefore, the aforesaid three algorithms still have a relatively high computation complexity, and hardware calculating circuits or registers required by the three algorithms are also relatively complicated.

Accordingly, an urgent need exists in the art to improve the aforesaid drawbacks in the conventional LDPC decoding algorithms

### SUMMARY

The disclosure includes a decoding method for a low-density parity check (LDPC) decoder. The LDPC decoder records an M×N parity check matrix related to M number of check nodes and N number of variable nodes. The decoding method may comprise: determining, by the LDPC decoder, j number of variable nodes related to a first check node according to the M×N parity check matrix; calculating, by the LDPC decoder, j number of node Logarithm Likelihood Ratio (LLR) values corresponding to the j number of variable nodes in a channel; determining, by the LDPC decoder, j number of initial check node to variable node (CN-VN) LLR values of the j number of variable nodes related to the first check node; calculating, by the LDPC decoder, j number of variable node to check node (VN-CN) LLR values according to the j number of node LLR values and the j number of initial CN-VN LLR values; calculating, by the LDPC decoder, j number of updated CN-VN LLR values of the j number of variable nodes related to the first check node according to the j number of VN-CN LLR values; calculating, by the LDPC decoder, j number of updated node LLR values according to the j number of updated CN-VN LLR values and the j number of VN-CN LLR values; and updating, by the LDPC decoder, the j number of node LLR values corresponding to the j number of variable nodes by using the j number of updated node LLR values.

The disclosure also includes an LDPC decoder which comprises a memory and a processing unit. The memory is configured to record an M×N parity check matrix related to M number of check nodes and N number of variable nodes. The processing unit is configured to: determine j number of variable nodes related to a first check node according to the M×N parity check matrix; calculate j number of node LLR values corresponding to the j number of variable nodes in a channel; determine j number of initial CN-VN LLR values of the j number of variable nodes related to the first check node; calculate j number of VN-CN LLR values according to the j number of node LLR values and the j number of initial CN-VN LLR values; calculate j number of updated CN-VN LLR values of the j number of variable nodes related to the first check node according to the j number of VN-CN LLR values; calculate j number of updated node LLR values according to the j number of updated CN-VN LLR values and the j number of VN-CN LLR values; and update the j number of node LLR values corresponding to the j number of variable nodes by using the j number of updated node LLR values.

The detailed technology and preferred embodiments implemented for the subject invention are described in the following paragraphs accompanying the appended drawings for people skilled in this field to well appreciate the features of the claimed invention.

### BRIEF DESCRIPTION OF THE DRAWINGS

FIG. 1A is a block diagram of an LDPC decoder according to a first embodiment of the present invention;

FIG. 1B is a schematic view of an M×N parity check matrix according to the first embodiment of the present invention;

FIG. 1C to FIG. 1D are Tanner views corresponding to the MxN parity check matrix according to the first embodiment of the present invention;

FIG. 2A is a schematic view of an M×N parity check matrix according to a second embodiment of the present invention;

FIG. 2B to FIG. 2C are Tanner views corresponding to the M×N parity check matrix according to the second embodiment of the present invention;

FIG. 3 is a flowchart diagram of a decoding method according to a third embodiment of the present invention; and

FIG. 4 is a flowchart diagram of a decoding method according to a fourth embodiment of the present invention.

### DETAILED DESCRIPTION

In the following description, the present invention will be explained with reference to certain example embodiments thereof. It shall be appreciated that, these example embodiments are not intended to limit the present invention to any particular examples, embodiments, environment, applications or implementations described in these example embodiments. Therefore, description of these example embodiments is only for purpose of illustration rather than to limit the present invention, and the scope claimed in this application shall be governed by the claims.

In the following embodiments and the attached drawings, elements unrelated to the present invention are omitted from depiction; and dimensional relationships among individual elements in the attached drawings are illustrated only for ease of understanding, but not to limit the actual scale.

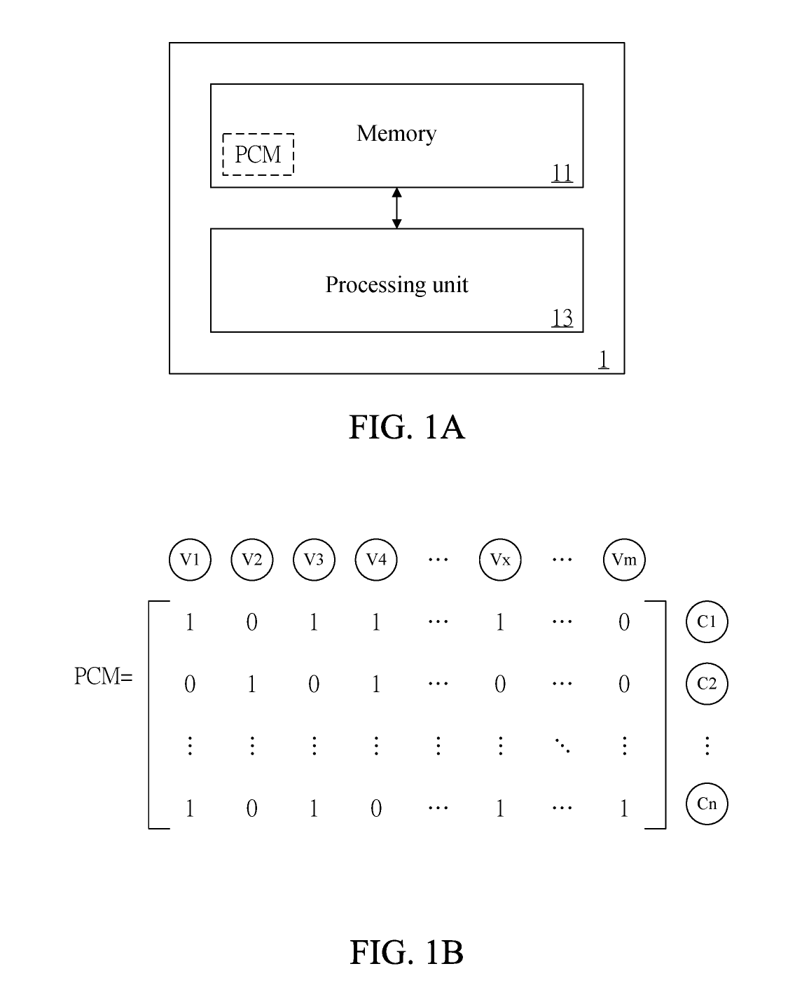

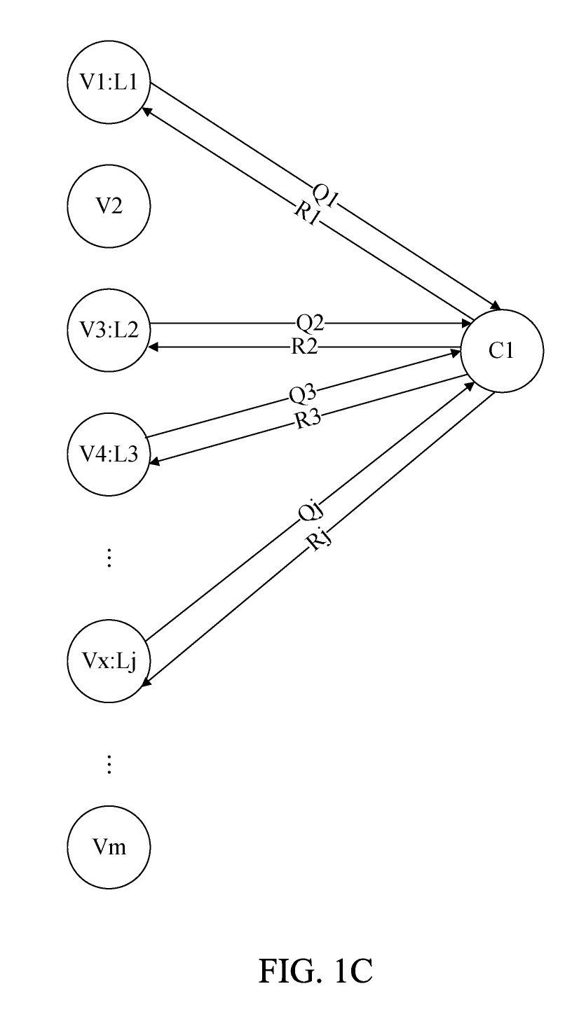

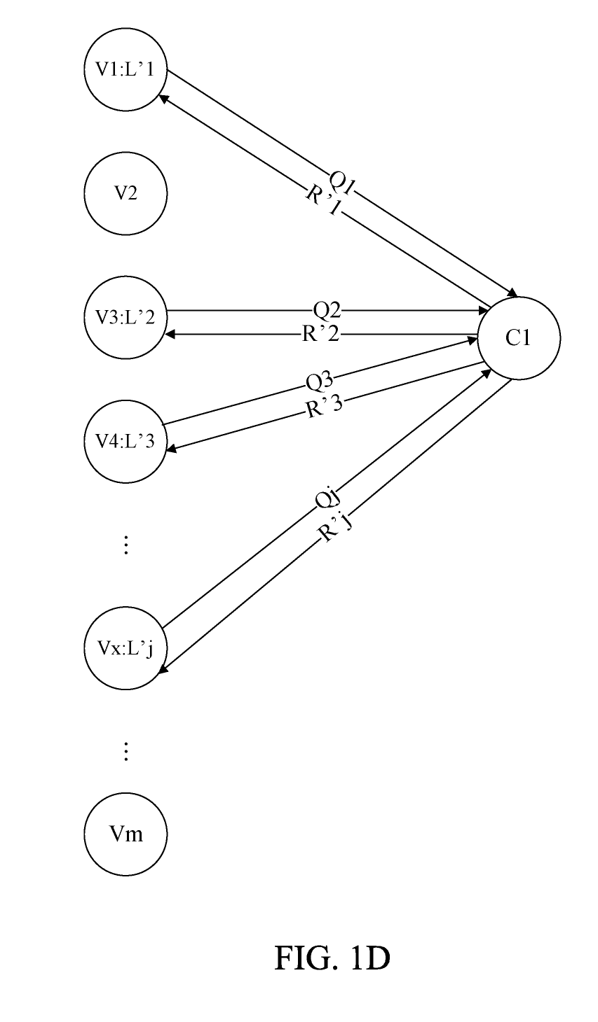

Please refer to FIG. 1A to FIG. 1D together. FIG. 1A is a block diagram of a low-density parity check (LDPC) decoder 1 according to a first embodiment of the present invention. The LDPC decoder 1 comprises a memory 11 and a processing unit 13, and the memory 11 records an M×N parity check matrix PCM related to M number of check nodes and N number of variable nodes.

FIG. 1B is a schematic view of the M×N parity check matrix PCM according to the first embodiment of the present invention. If a matrix element (m,n) is 1, then it means that there is a connection between a check node m and a variable node n. On the contrary, if the matrix element (m,n) is 0, then it means that there is no connection between the check node m and the variable node n. FIG. 1C to FIG. 1D are Tanner views corresponding to the M×N parity check matrix PCM according to the first embodiment of the present invention. These elements are electrically connected together, and interactions among these elements will be further described hereinafter. First, as shown in FIG. 1B and FIG. 1C, the processing unit 13 of the LDCP decoder 1 determines j number of variable nodes V1, V3, V4 . . . Vx related to a first check node C1 according to the M×N parity check matrix PCM. Thereafter, the processing unit 13 of the LDCP decoder 1 calculates j number of node Logarithm Likelihood Ratio (LLR) values L1, L2, L3 . . . Lj corresponding to the j number of variable nodes V1, V3, V4 . . . Vx in a channel. Next, the processing unit 13 of the LDPC decoder 1 determines j number of initial check node to variable node (CN-VN) LLR values R1, R2, R3 . . . Rj of the j number of variable nodes V1, V3, V4 . . . Vx related to the first check node C1. Accordingly, the processing unit 13 of the LDPC decoder 1 can calculate j number of variable node to check node (VN-CN) LLR values Q1, Q2, Q3 . . . Qj according to the j number of node LLR values L1, L2, L3 . . . Lj and the j number of initial CN-VN LLR values R1, R2, R3 . . . Rj.

Thereafter, as shown in FIG. 1D, the processing unit 13 of the LDPC decoder 1 calculates j number of updated CN-VN LLR values R′1, R′2, R′3 . . . R′j of the j number of variable nodes V1, V3, V4 . . . Vx related to the first check node C1 according to the j number of VN-CN LLR values Q1, Q2, Q3 . . . Qj. Next, the processing unit 13 of the LDPC decoder 1 can calculate j number of updated node LLR values L′1, L′2, L′3 . . . L′j according to the j number of updated CN-VN LLR values R′1, R′2, R′3 . . . R′j and the j number of VN-CN LLR values Q1, Q2, Q3 . . . Qj.

Finally, the processing unit 13 of the LDPC decoder 1 updates the j number of node LLR values L1, L2, L3 . . . Lj corresponding to the j number of variable nodes V1, V3, V4 . . . Vx by directly using the j number of updated node LLR values L′1, L′2, L′3 . . . L′j related to the single check node C1.

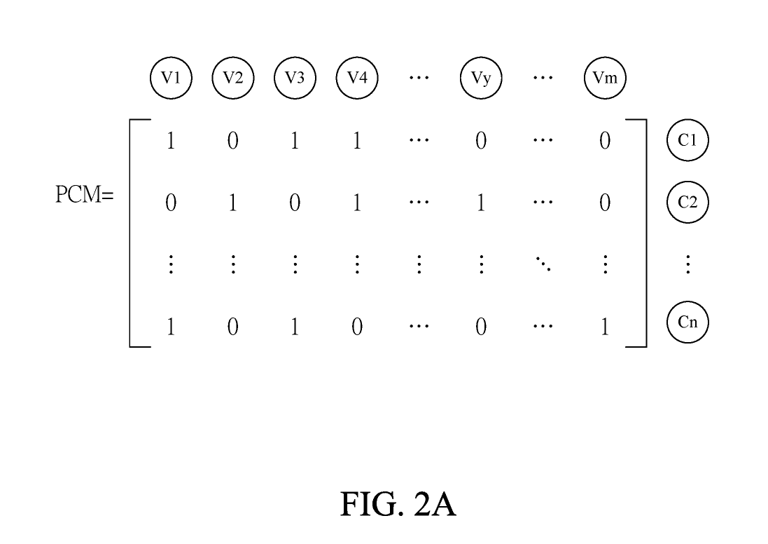

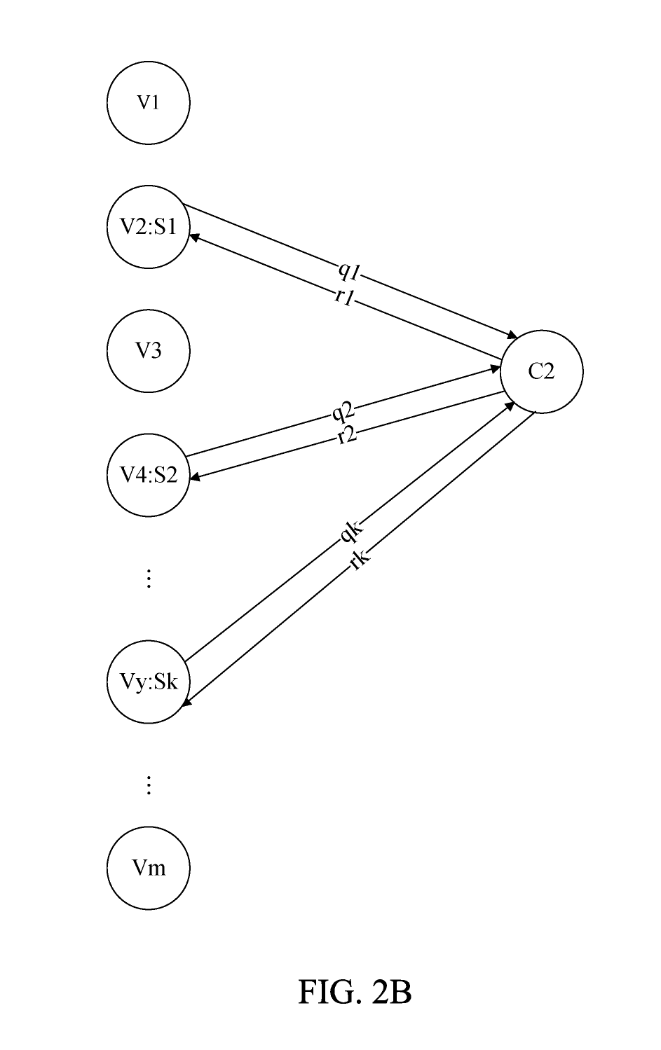

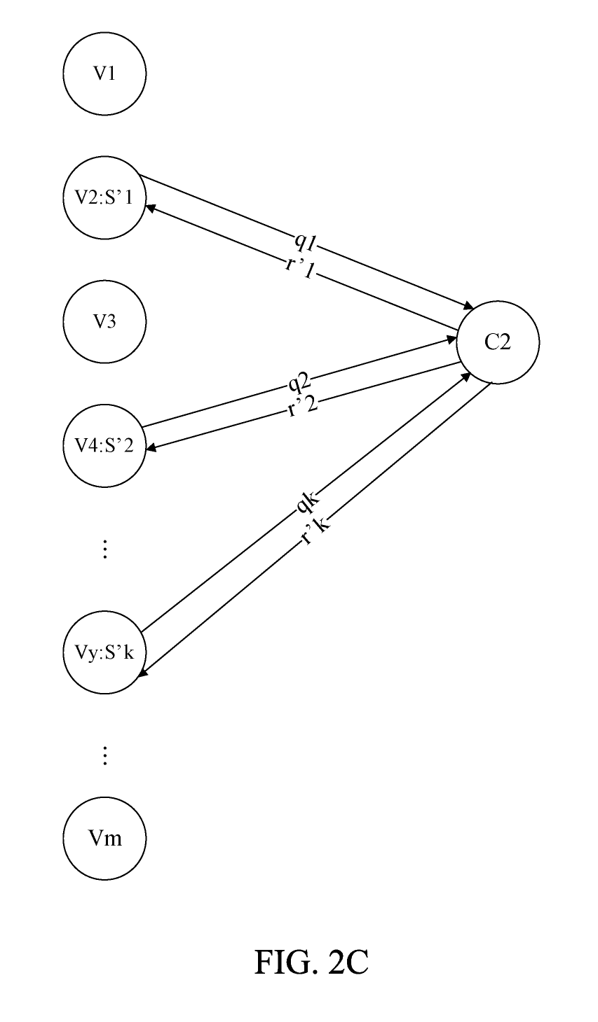

Please refer to FIG. 2A to FIG. 2C. FIG. 2A is a schematic view of an M×N parity check matrix PCM according to a second embodiment of the present invention. FIG. 2B to FIG. 2C are Tanner views corresponding to the M×N parity check matrix PCM according to the second embodiment of the present invention. The architecture of the second embodiment is similar to that of the first embodiment, so elements labeled by same symbols have same functions and thus will not be further described herein. As the continuation of the first embodiment, the second embodiment is mainly configured to further describe that the LDPC decoder 1 of the present invention repeatedly performs the steps of updating the node LLR values of variable nodes for other check nodes.

First, as shown in FIG. 2A to FIG. 2C, the processing unit 13 of the LDPC decoder 1 determines k number of variable nodes V2, V4 . . . Vy related to a second check node C2 according to the M×N parity check matrix PCM. Thereafter, the processing unit 1 of the LDPC decoder 1 calculates k number of node LLR values S1, S2 . . . Sk corresponding to the k number of variable nodes V2, V4 . . . Vy.

It shall be particularly appreciated that, node LLR values (e.g., node LLR values S1 and Sy) corresponding to the variable nodes, of which the node LLR values have not been updated (e.g., the variable nodes V2 and Vy), in the channel will be directly calculated by the processing unit 13 of the LDPC decoder 1 in the second embodiment. However, the node LLR values used by the variable nodes, of which the node LLR values have been updated previously (e.g., the variable node V4), are right the node LLR values that have been updated for the previous check node (e.g., the first check node). In other words, the node LLR value S2 of the second embodiment is the updated node LLR value L′3 of the first embodiment.

Next, similarly, the processing unit 13 of the LDPC decoder 1 determines k number of initial LLR values r1, r2 . . . rk of the k number of variable nodes V2, V4 . . . Vy related to the second check node C2. Accordingly, the processing unit 13 of the LDPC decoder 1 can calculate k number of VN-CN LLR values q1, q2 . . . qk according to the k number of node LLR values S1, S2 . . . Sk and the k number of initial CN-VN LLR values r1, r2 . . . rk.

Thereafter, as shown in FIG. 2C, the processing unit 13 of the LDPC decoder 1 calculates k number of updated CN-VN LLRs r′1, r′2 . . . r′k of the k number of variable nodes V2, V4 . . . Vy related to the second check node C2 according to the k number of VN-CN LLR values q1, q2 . . . qk. Next, the processing unit 13 of the LDPC decoder 1 can calculate k number of updated node LLR values S′1, S′2 . . . S′k according to the k number of updated CN-VN LLR values r′1, r′2 . . . r′k and the k number of VN-CN LLR values q1, q2 . . . qk.

Finally, the processing unit 13 of the LDPC decoder 1 updates the k number of node LLR values S1, S2 . . . Sk corresponding to the k number of variable nodes V2, V4 . . . Vy by directly using the k number of updated node LLR values S′1, S′2 . . . S′k related to the single check node C2. In this way, the LDPC decoder 1 of the present invention can directly update the node LLR values of the corresponding variable nodes for a single check node, and repeat the operation of updating the node LLR values of the variable nodes sequentially for other check nodes by using the updated node LLR values of the variable nodes. In this way, the time complexity and the space complexity can also be reduced effectively to greatly save time and hardware required for decoding.

It shall be particularly appreciated that, in the operational details of the aforesaid embodiments, the processing unit 13 of the LDPC decoder 1: takes a value of subtracting each CN-VN LLR value from a corresponding node LLR value as each VN-CN LLR value (e.g., Q1=L1−R1); and takes a value of adding each VN-CN LLR value to a corresponding updated CN-VN LLR value as each updated node LLR value (e.g., L′1=Q1+R′1=L1−R1+R′1).

Moreover, the processing unit 13 of the LDPC decoder 1 calculates the updated CN-VN LLRs of the variable nodes related to the check node based on the following formula:

$${R}_{m , n}^{′} = S \cdot {\prod }_{i ∈ {N}_{m} \backslash n} sign ( {Q}_{m , i} ) \cdot {min}_{i ∈ {N}_{m} \backslash n} \vert {Q}_{m , i} \vert$$

while R′m,n is an updated CN-VN LLR value from the m^{th} check node to the n^{th} variable node. S is an adjustment parameter that is set by a user depending on different usage conditions. Nm\n represents variable nodes related to the m^{th} check node except for the n^{th} variable node. Qm,i is the VN-CN LLR value from the iₜₕ variable node to the m^{th} check node.

It shall be emphasized that, the key point of the present invention mainly lies in that: the LLRs of the variable nodes can be first updated for a single check node, and then the operation of updating the LLR values of the variable nodes is repeated sequentially for other check nodes. In other words, by adjusting the operational process, the present invention can remarkably reduce the time and the space complexity while maintaining a certain level of decoding accuracy. The application of the parity check matrix as well as the meaning and the calculating methods of various LLR values shall be appreciated by those skilled in the art depending on the above disclosure, and thus will not be further described herein.

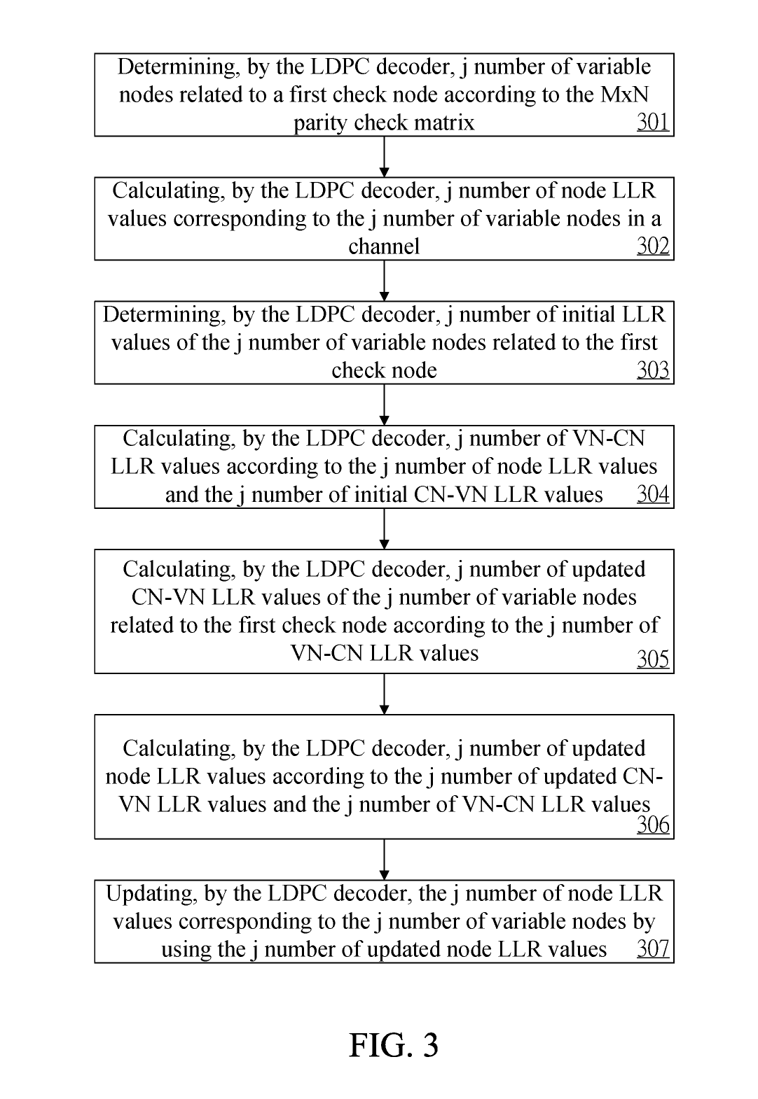

A third embodiment of the present invention is a decoding method, and a flowchart diagram thereof is as shown in FIG. 3. The method of the third embodiment is for use in an LDPC decoder (e.g., the LDPC decoder of the aforesaid embodiments). The LDPC decoder records an M×N parity check matrix related to M number of check nodes and N number of variable nodes. Detailed steps of the third embodiment are as follows.

First, step 301 is executed to determine, by the LDPC decoder, j number of variable nodes related to a first check node according to the M×N parity check matrix. Step 302 is executed to calculate, by the LDPC decoder, j number of node LLR values corresponding to the j number of variable nodes in a channel Step 303 is executed to determine, by the LDPC decoder, j number of initial LLR values of the j number of variable nodes related to the first check node.

Next, step 304 is executed to calculate, by the LDPC decoder, j number of VN-CN LLR values according to the j number of node LLR values and the j number of initial CN-VN LLR values. Step 305 is executed to calculate, by the LDPC decoder, j number of updated CN-VN LLR values of the j number of variable nodes related to the first check node according to the j number of VN-CN LLR values. Step 306 is executed to calculate, by the LDPC decoder, j number of updated node LLR values according to the j number of updated CN-VN LLR values and the j number of VN-CN LLR values. Finally, step 307 is executed to update, by the LDPC decoder, the j number of node LLR values corresponding to the j number of variable nodes by using the j number of updated node LLR values.

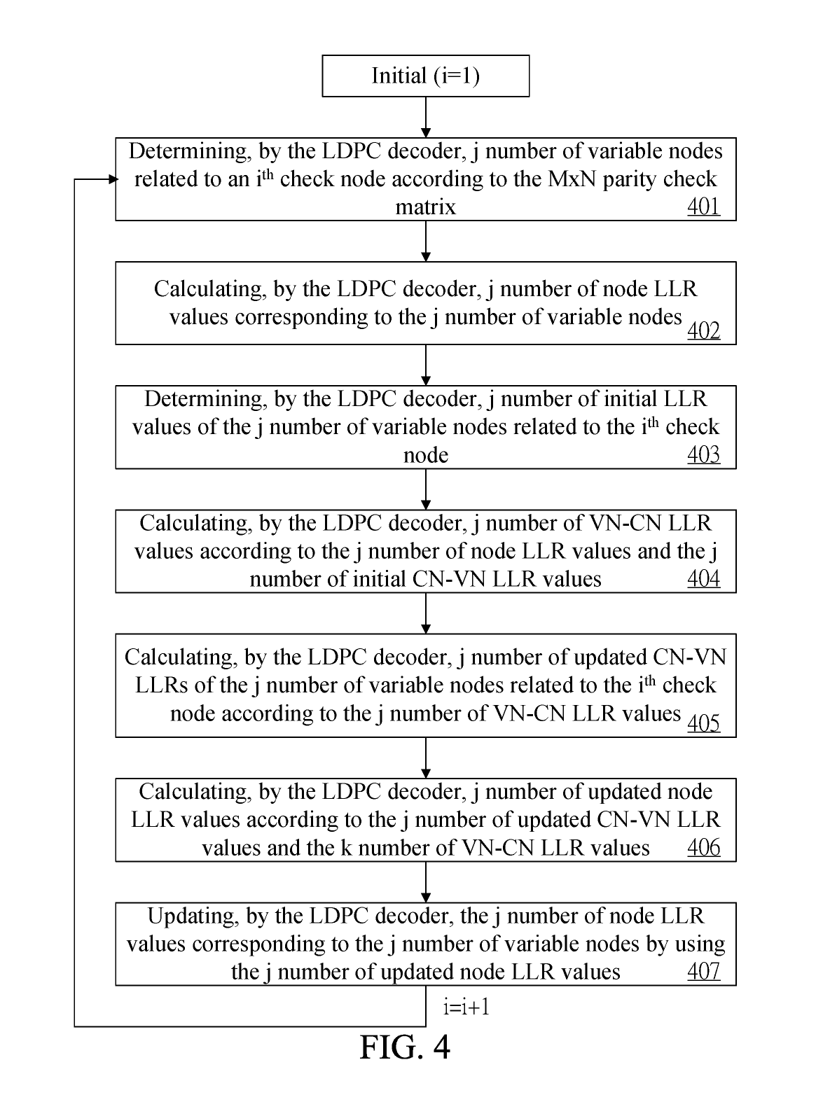

A fourth embodiment of the present invention is a decoding method, and a flowchart diagram thereof is as shown in FIG. 4. The method of the fourth embodiment is for use in an LDPC decoder (e.g., the LDPC decoder of the aforesaid embodiments). The LDPC decoder records an M×N parity check matrix related to M number of check nodes and N number of variable nodes. Detailed steps of the fourth embodiment are as follows.

First, step 401 is executed to determine, by the LDPC decoder, j number of variable nodes related to an i^{th} check node according to the M×N parity check matrix. i has an initial value of 1. Step 402 is executed to calculate, by the LDPC decoder, j number of node LLR values corresponding to the j number of variable nodes. Step 403 is executed to determine, by the LDPC decoder, j number of initial LLR values of the j number of variable nodes related to the i^{th} check node.

Next, step 404 is executed to calculate, by the LDPC decoder, j number of VN-CN LLR values according to the j number of node LLR values and the j number of initial CN-VN LLR values. Step 405 is executed to calculate, by the LDPC decoder, j number of updated CN-VN LLRs of the j number of variable nodes related to the i^{th} check node according to the j number of VN-CN LLR values. Step 406 is executed to calculate, by the LDPC decoder, j number of updated node LLR values according to the j number of updated CN-VN LLR values and the j number of VN-CN LLR values. Finally, step 407 is executed to update, by the LDPC decoder, the j number of node LLR values corresponding to the j number of variable nodes by using the j number of updated node LLR values.

It shall be particularly appreciated that, if at least one check node among the N number of check nodes has not been processed, then the aforesaid steps are repeated for the next check node after enabling i=i+1 in the fourth embodiment. A complete decoding iteration is finished until all of the N number of check nodes have been processed via the aforesaid steps.

According to the above descriptions, the LDPC decoder and the decoding method of the present invention can directly update the node LLR values of corresponding variable nodes for a single check node to finish one sub-iteration. Thereafter, different sub-iterations are performed sequentially for other check nodes by using the updated node LLR values of the variable nodes, and one iteration is finished until all of the check nodes have been processed. In this way, the time complexity and the space complexity for decoding of the present invention are indeed improved by at least one level as compared to the prior art, thereby greatly saving time and hardware required for decoding and improving the drawbacks of the prior art.

The above disclosure is related to the detailed technical contents and inventive features thereof. People skilled in this field may proceed with a variety of modifications and replacements based on the disclosures and suggestions of the invention as described without departing from the characteristics thereof. Nevertheless, although such modifications and replacements are not fully disclosed in the above descriptions, they have substantially been covered in the following claims as appended.

What is claimed is:

1. A decoding method for a low-density parity check (LDPC) decoder, the LDPC decoder recording an M×N parity check matrix related to M number of check nodes and N number of variable nodes, the decoding method comprising:
determining, by the LDPC decoder, j number of variable nodes related to a first check node according to the M×N parity check matrix;
calculating, by the LDPC decoder, j number of node Logarithm Likelihood Ratio (LLR) values corresponding to the j number of variable nodes in a channel;
determining, by the LDPC decoder, j number of initial check node to variable node (CN-VN) LLR values of the j number of variable nodes related to the first check node;
calculating, by the LDPC decoder, j number of variable node to check node (VN-CN) LLR values according to the j number of node LLR values and the j number of initial CN-VN LLR values;
calculating, by the LDPC decoder, j number of updated CN-VN LLR values of the j number of variable nodes related to the first check node according to the j number of VN-CN LLR values;
calculating, by the LDPC decoder, j number of updated node LLR values according to the j number of updated CN-VN LLR values and the j number of VN-CN LLR values; and
updating, by the LDPC decoder, the j number of node LLR values corresponding to the j number of variable nodes by using the j number of updated node LLR values.

2. The decoding method of claim 1, further comprising:
determining, by the LDPC decoder, k number of variable nodes related to a second check node according to the M×N parity check matrix;
calculating, by the LDPC decoder, k number of node LLR values corresponding to the k number of variable nodes;
determining, by the LDPC decoder, k number of initial CN-VN LLR values of the k number of variable nodes related to the second check node;
calculating, by the LDPC decoder, k number of VN-CN LLR values according to the k number of node LLR values and the k number of initial CN-VN LLR values;
calculating, by the LDPC decoder, k number of updated CN-VN LLRs of the k number of variable nodes related to the second check node according to the k number of VN-CN LLR values;
calculating, by the LDPC decoder, k number of updated node LLR values according to the k number of updated CN-VN LLR values and the k number of VN-CN LLR values; and
updating, by the LDPC decoder, the k number of node LLR values corresponding to the k number of variable nodes by using the k number of updated node LLR values.

3. The decoding method of claim 1, wherein the step of calculating, by the LDPC decoder, the j number of VN-CN LLR values according to the j number of node LLR values and the j number of initial CN-VN LLR values further comprises:
taking, by the LDPC decoder, a value of subtracting each of the j number of CN-VN LLR values from a corresponding one of the j number of node LLR values respectively as each of the j number of VN-CN LLR values.

4. The decoding method of claim 1, wherein the LDPC decoder calculates the j number of updated CN-VN LLRs of the j number of variable nodes related to the first check node based on the following formula:
$${R}_{m , n}^{′} = S \cdot {\prod }_{i ∈ {N}_{m} \backslash n} sign ( {Q}_{m , i} ) \cdot {min}_{i ∈ {N}_{m} \backslash n} \vert {Q}_{m , i} \vert$$
wherein, R′_{m,n} is an updated CN-VN LLR value from the m^{th} check node to the n^{th} variable node, S is an adjustment parameter, Nₘ\n represents variable nodes related to the m^{th} check node except for the n^{th} variable node, and Qm,j is the VN-CN LLR value from the n^{th} variable node to the n^{th} check node.

5. The decoding method of claim 1, wherein the step of calculating, by the LDPC decoder, j number of updated node LLR values according to the j number of updated CN-VN LLR values and the j number of VN-CN LLR values further comprises:
taking, by the LDPC decoder, a value of adding each of the j number of VN-CN LLR values to a corresponding one of the j number of updated CN-VN LLR values as each of the j number of updated node LLR values.

6. A low-density parity check (LDPC) decoder, comprising:
a memory, recording an M×N parity check matrix related to M number of check nodes and N number of variable nodes, and
a processing unit, being configured to:
determine j number of variable nodes related to a first check node according to the M×N parity check matrix;
calculate j number of node Logarithm Likelihood Ratio (LLR) values corresponding to the j number of variable nodes in a channel;
determine j number of initial check node to variable node (CN-VN) LLR values of the j number of variable nodes related to the first check node;
calculate j number of variable node to check node (VN-CN) LLR values according to the j number of node LLR values and the j number of initial CN-VN LLR values;
calculate j number of updated CN-VN LLR values of the j number of variable nodes related to the first check node according to the j number of VN-CN LLR values;
calculate j number of updated node LLR values according to the j number of updated CN-VN LLR values and the j number of VN-CN LLR values; and
update the j number of node LLR values corresponding to the j number of variable nodes by using the j number of updated node LLR values.

7. The LDPC decoder of claim 6, wherein the processor is further configured to:
determine k number of variable nodes related to a second check node according to the M×N parity check matrix;
calculate k number of node LLR values corresponding to the k number of variable nodes;
determine k number of initial CN-VN LLR values of the k number of variable nodes related to the second check node;
calculate k number of VN-CN LLR values according to the k number of node LLR values and the k number of initial CN-VN LLR values;
calculate k number of updated CN-VN LLRs of the k number of variable nodes related to the second check node according to the k number of VN-CN LLR values;
calculate k number of updated node LLR values according to the k number of updated CN-VN LLR values and the k number of VN-CN LLR values; and
update the k number of node LLR values corresponding to the k number of variable nodes by using the k number of updated node LLR values.

8. The LDPC decoder of claim 6, wherein the processing unit takes a value of subtracting each of the j number of CN-VN LLR values from a corresponding one of the j number of node LLR values respectively as each of the j number of VN-CN LLR values.

9. The LDPC decoder of claim 6, wherein the processing unit calculates the j number of updated CN-VN LLRs of the j number of variable nodes related to the first check node based on the following formula:
$${R}_{m , n}^{′} = S \cdot {\prod }_{i ∈ {N}_{m} \backslash n} sign ( {Q}_{m , i} ) \cdot {min}_{i ∈ {N}_{m} \backslash n} \vert {Q}_{m , i} \vert$$
wherein, R′_{m,n} is an updated CN-VN LLR value from the m^{th} check node to the n^{th} variable node, S is an adjustment parameter, Nₘ\n represents variable nodes related to the m^{th} check node except for the n^{th} variable node, and Qm,j is the VN-CN LLR value from the n^{th} variable node to the n^{th} check node.

10. The LDPC decoder of claim 6, wherein the processing unit takes a value of adding each of the j number of VN-CN LLR values to a corresponding one of the j number of updated CN-VN LLR values as each of the j number of updated node LLR values.
